(19) United States
(12) Patent Application Publication
(10) Pub. No.: US 2025/0273381 A1
(43) Pub. Date: Aug. 28, 2025

(54) TRANSFORMER ASSEMBLIES AND TRANS-INDUCTANCE VOLTAGE REGULATION

(71) Applicant: Infineon Technologies Austria AG, Villach (AT)

(72) Inventors: Wenkang Huang, East Greenwich, CT (US); Danny R. Clavette, Greene, RI (US)

(21) Appl. No.: 18/584,230

(22) Filed: Feb. 22, 2024

(51) Int. Cl. H01F 27/28; H01F 27/24; H01F 27/42; H01F 41/04

(52) U.S. Cl. CPC H01F 27/28; H01F 27/24; H01F 41/04; H01F 27/42

(57) ABSTRACT

An assembly as discussed herein includes a layer of magnetically permeable material, a first transformer winding pair, a second transformer winding pair, and a first electrically conductive path. The first winding pair includes a first primary winding path and a first secondary winding path extending through the magnetically permeable material. The second winding pair includes a second primary winding path and a second secondary winding path extending through the magnetically permeable material. The assembly as discussed herein includes any number of additional transformer winding pairs, each of which includes a respective primary winding path and a secondary winding path. A series circuit path including the first electrically conductive path couples the first secondary winding path in series with the second secondary winding path and, if present, the additional secondary winding paths. Such a configuration supports a trans-inductance voltage regulator.

### BACKGROUND

A printed circuit board (PCB) or printed wiring board is a laminated structure of conductive layers separated by insulating layers. In general, PCBs have two functions. The first is to secure electronic components at designated locations on the outer layers of the PCB by means of affixing such as soldering. The electronic circuit instantiated by the populated circuit board is designed to provide one or more specific functions. After fabrication, the electronic circuit is powered to perform the desired functions.

Typically, a printed circuit board is a planar device on which multiple components are interconnected via traces to provide the functions as previously discussed. Such implementations of fabricating circuitry on a planar circuit board assembly is dimensionally limited, preventing high density implementation of circuitry.

It is further noted that a conventional TLVR (Trans-inductance Voltage Regulator) system is generally a voltage regulator (e.g. a buck converter) where the magnetic device is no longer a single-winding inductor, but a transformer with two windings; where the primary windings constitute the phase inductors. The secondary windings are the so called TLVR windings, which are used to improve the transient performance. The conventional TLVR voltage regulator receives an input voltage and produces an output voltage to power a load.

### BRIEF DESCRIPTION

Implementation of clean energy (or green technology) is very important to reduce our impact as humans on the environment. In general, clean energy includes any evolving methods and materials to reduce an overall toxicity of energy consumption on the environment.

This disclosure includes the observation that raw energy, such as received from green energy sources or non-green energy sources, typically needs to be converted into an appropriate form (such as desired AC voltage, DC voltage, etc.) before it can be used to power end devices such as servers, computers, mobile communication devices, etc. Regardless of whether energy is received from green energy sources or non-green energy sources, it is desirable to make most efficient use of raw energy provided by such systems to reduce our impact on the environment. This disclosure contributes to reducing our carbon footprint (and green energy) via more efficient energy conversion and circuit implementations supporting same.

As discussed herein, a fabricator produces one or more assemblies to provide higher density circuitry than provided by conventional instantiation of voltage regulator circuitry on planar circuit boards.

More specifically, this disclosure includes an apparatus, systems, methods, etc. For example, an apparatus comprising: a layer of magnetically permeable material; a first winding pair including a first primary winding path and a first secondary winding path extending through the magnetically permeable material; a second winding pair including a second primary winding path and a second secondary winding path extending through the magnetically permeable material; and a first electrically conductive path coupling the first secondary winding path in series with the second secondary winding path.

In one example, a first portion of the first electrically conductive path extends through the layer of magnetically permeable material between a first node on a first surface of the layer and a second node on a second surface of the layer. A second portion of the first electrically conductive path extends adjacent to the first surface of the layer between the first secondary winding path and the first node; and a third portion of the first electrically conductive path extends adjacent to the second surface of the layer between the second secondary winding path and the second node.

In accordance with still further examples, the first electrically conductive path as discussed herein does not pass through the layer of magnetically permeable material. In such an example, the first secondary winding path extends axially to a first node on a first surface of the layer; the second secondary winding path extends axially to a second node on a second surface of the layer; and the first electrically conductive path extends between the first node and the second node.

In accordance with another example as discussed herein, the apparatus further includes: a third winding pair including a third primary winding path and a third secondary winding path extending through the magnetically permeable material; a fourth winding pair including a fourth primary winding path and a fourth secondary winding path extending through the magnetically permeable material; and a second electrically conductive path coupling the third secondary winding path in series with the fourth secondary winding path. In such an example, a third electrically conductive path may couple the second secondary winding path in series with the third secondary winding path; and a fourth electrically conductive path may couple the fourth secondary winding path in series with the first secondary winding path.

The apparatus may further include a first node; a second node; and a series circuit path extending between the first node and the second node, the series circuit path connecting a combination of the first secondary winding, second secondary winding, third secondary winding, and the fourth secondary winding in series with each other. The series circuit path passes through the layer of magnetically permeable material multiple times.

In yet a further example, the apparatus includes a circuit component disposed between a first node and a second node; the first electrically conductive path may be a series circuit path extending between the first node and the second node. In the series circuit path may connect a combination of the first secondary winding and the second secondary winding in series. In one example, the circuit component is an inductor.

In accordance with another example as discussed herein, the apparatus may include: a third winding pair including a third primary winding path and a third secondary winding path extending through the magnetically permeable material; a fourth winding pair including a fourth primary winding path and a fourth secondary winding path extending through the magnetically permeable material; and a series circuit path including the first electrically conductive path, the series circuit path connecting the first secondary winding path, second secondary winding path, third secondary winding path and the fourth secondary winding path in series. If desired, the first primary winding path may be disposed diagonally across from the third primary winding path; the second primary winding path may be disposed diagonally across from the fourth primary winding path; the first secondary winding path and the third secondary winding path may be disposed between the first primary winding path and the third primary winding path; and the second secondary winding path and the fourth secondary winding path may be disposed between the second primary winding path and the fourth primary winding path.

Still further, note that a combination of the first primary winding path and the third primary winding path may be disposed between the first secondary winding path and the third secondary winding path; and a combination of the second primary winding path and the fourth primary winding path may be disposed between the second secondary winding path and the fourth secondary winding path.

Yet further, a portion of the series circuit path as discussed herein may reside outside of a volumetric portion of the magnetically permeable material disposed between a combination of the first primary winding path, second primary winding path, third primary winding path, and fourth primary winding path.

In yet another example, the layer of magnetically permeable material is a first substrate. The apparatus may further include: a second substrate, the first substrate affixed to the second substrate; and switch circuitry disposed on the second substrate, the switch circuitry operative to control first current through the first primary winding path and second current through the second primary winding path. The apparatus may further include: a third substrate, the first substrate affixed to the third substrate; and a dynamic load powered by the first current and the second current, the third substrate disposed between the first substrate and the dynamic load.

As further discussed herein, the apparatus may include: a first substrate, wherein the layer of magnetically permeable material is embedded within the first substrate; and switch circuitry operative to control first current through the first primary winding path and second current through the second primary winding path. The apparatus may further include: a circuit component powered by the first current and the second current; and a second substrate, the first substrate affixed to the second substrate, the first substrate disposed between the second substrate and the circuit component.

Still further examples herein include a method comprising: receiving magnetically permeable material; fabricating a first winding pair to include a first primary winding path and a first secondary winding path extending through the magnetically permeable material; fabricating a second winding pair to include a second primary winding path and a second secondary winding path extending through the magnetically permeable material; and via a first electrically conductive path, coupling the first secondary winding path in series with the second secondary winding path.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be embodied and viewed in many different ways.

Also, note that this preliminary discussion of techniques herein (BRIEF DESCRIPTION) purposefully does not specify every novel aspect of the present disclosure or claimed invention(s). Instead, this brief description only presents general aspects and corresponding points of novelty over conventional techniques. For additional details and/or possible perspectives (permutations) of the invention(s), the reader is directed to the Detailed Description section (which is a summary) and corresponding figures of the present disclosure as further discussed below.

### BRIEF DESCRIPTION OF THE DRAWINGS

FIG. 1 is an example 3-D (3-Dimensional) diagram illustrating a transformer assembly as discussed herein.

FIG. 2 is an example 3-D diagram of a transformer assembly as discussed herein.

FIG. 3 is an example 3-D diagram illustrating another implementation of a transformer assembly as discussed herein.

FIG. 4 is an example top view diagram of the transformer assembly in FIG. 3 as discussed herein.

FIG. 5 is an example circuit diagram including implementation of any of the transformer assemblies as discussed herein.

FIG. 6 is an example 3-Dimensional (3-D) diagram illustrating an open circuit implementation of a transformer assembly (a.k.a., power converter assembly) as discussed herein.

FIG. 7 is an example 3-Dimensional (3-D) diagram illustrating an open circuit implementation of a transformer assembly as discussed herein.

FIG. 8A is an example diagram illustrating a substrate and corresponding circuit components associated with a power converter assembly as discussed herein.

FIG. 8B is an example diagram illustrating a power converter circuit including a substrate and transformer assembly as discussed herein.

FIG. 9 is an example 3-Dimensional diagram illustrating stacking of assemblies and/or circuit boards as discussed herein.

FIGS. 10A and 10B are example 3-Dimensional diagrams illustrating implementation of a transformer assembly between a host substrate and a respective load as discussed herein.

FIG. 11 is an example diagram illustrating implementation of a transformer assembly as discussed herein.

FIG. 12 is an example method of fabricating a respective transformer assembly as discussed herein.

The foregoing and other objects, features, and advantages of the disclosed matter herein will be apparent from the following more particular description herein, as illustrated in the accompanying drawings in which like reference characters refer to the same parts throughout the different views. The drawings are not necessarily to scale, with emphasis instead being placed upon illustrating the principles, concepts, aspects, techniques, etc.

### DETAILED DESCRIPTION

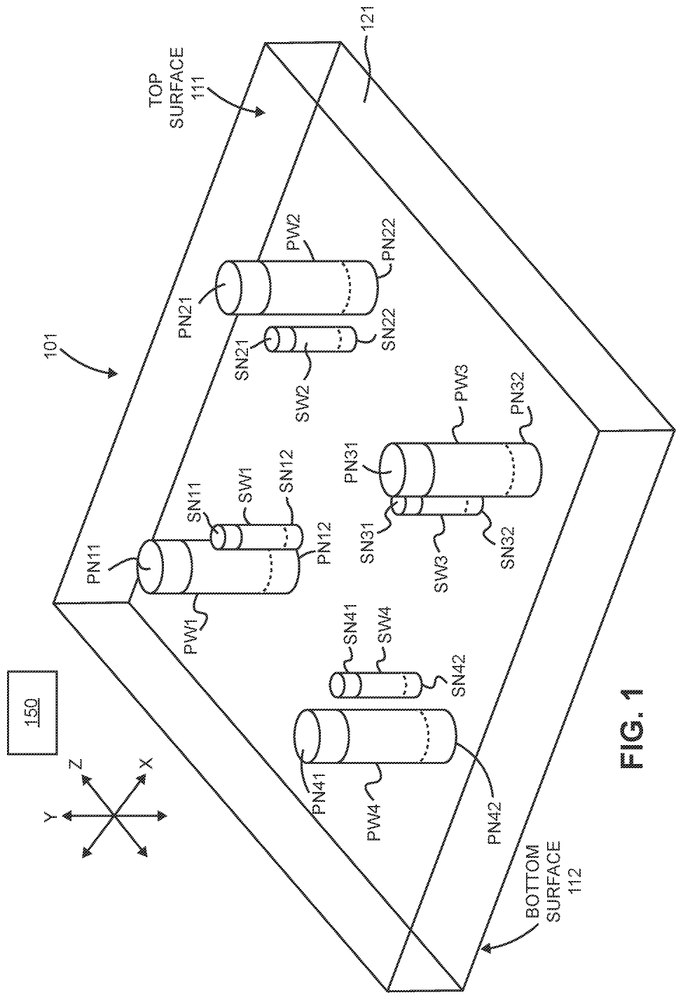

Now, more specifically, FIG. 1 is an example 3D diagram illustrating preliminary assembly of a transformer assembly (a.k.a., power converter assembly) as discussed herein.

In this example, a transformer assembly fabricator 150 or other suitable entity produces the assembly 101 to include any number of multiple transformer winding pairs. Each pair of primary winding and secondary winding represents a transformer disposed in the or through the layer of magnetically permeable material 121.

For example, the fabricator 150 receives or produces a layer of magnetically permeable material 121. The fabricator 150 produces the transformer assembly 101 to include a first transformer winding pair including a first primary winding path PW1 and a first secondary winding path SW1 to extend at least from the top surface 111 of the layer 121 through the layer 121 to at least the bottom surface 112 of the layer of magnetically permeable material 121. Via the layer of magnetically permeable material 121, the secondary winding SW1 is magnetically or inductively coupled to the primary winding PW1.

The fabricator 150 produces the transformer assembly 101 to further include a second transformer winding pair including a second primary winding path PW2 and a second secondary winding path SW2 to extend at least from the top surface 111 of the layer 121 through the layer 121 to at least the bottom surface 112 of the layer of magnetically permeable material 121. Via the layer of magnetically permeable material 121, the secondary winding SW2 is magnetically or inductively coupled to the primary winding PW2.

The fabricator 150 further produces the transformer assembly 101 to include a third transformer winding pair including a third primary winding path PW3 and a third secondary winding path SW3 to extend at least from the top surface 111 of the layer 121 through the layer 121 to at least the bottom surface 112 of the layer of magnetically permeable material 121. Via the layer of magnetically permeable material 121, the secondary winding SW3 is magnetically or inductively coupled to the primary winding PW3.

The fabricator 150 produces the transformer assembly 101 to include a fourth transformer winding pair including a fourth primary winding path PW4 and a fourth secondary winding path SW4 to extend at least from the top surface 111 of the layer 121 through the layer 121 to at least the bottom surface 112 of the layer of magnetically permeable material 121. Via the layer of magnetically permeable material 121, the secondary winding SW4 is magnetically or inductively coupled to the primary winding PW4.

In this manner, the fabricator 150 produces the transformer assembly 101 to include any number of transformer winding pairs.

Note that each of the primary winding paths (electrically conductive paths) and the secondary winding paths (electrically conductive paths) as discussed herein can be fabricated from metal such as copper or any suitable one or more electrically conductive materials.

Additionally, note that the fabrication of the assembly 101 can include drilling holes in the layer of magnetically permeable material 121 and subsequent insertion of the respective primary winding paths and the secondary winding paths in the drilled holes. Alternatively, fabrication of the assembly 101 can include injection of appropriate material in a respective mold to produce the layer of magnetically permeable material 121 such that each of the transformer windings extends between the top surface 111 and the bottom surface 112.

In one example, each of the transformer windings (such as PW1, SW1, PW2, SW2, PW3, SW3, PW4, SW4, etc.) can extend axially along the y-axis. The top surface 111 of the assembly 101 resides parallel to the X-Z plane. The bottom surface 112 of the assembly 101 resides parallel to the X-Z plane as well. Accordingly, each of the transformer windings can be configured to extend orthogonally through the layer of magnetically permeable material 121.

In accordance with further examples, note that each of the transformer windings can be fabricated in any suitable shape such as cylinder, etc. Further, note that each of the primary transformer windings may be of a first diameter while each of the secondary windings may be of a second diameter, wherein the first diameter is larger than the second diameter.

Additionally, as shown, the primary transformer winding PW1 extends between the node PN11 exposed on the top surface 111 and the node PN12 exposed on the bottom surface 112 of the magnetically permeable material 121; the primary transformer winding PW2 extends between the node PN21 exposed on the top surface 111 and the node PN22 exposed on the bottom surface 112 of the magnetically permeable material 121; the primary transformer winding PW3 extends between the node PN31 exposed on the top surface 111 and the node PN32 exposed on the bottom surface 112 of the magnetically permeable material 121; the primary transformer winding PW4 extends between the node PN41 exposed on the top surface 111 and the node PN42 exposed on the bottom surface 112 of the magnetically permeable material 121.

The secondary transformer winding SW1 extends between the node SN11 exposed on the top surface 111 and the node SN12 exposed on the bottom surface 112 of the magnetically permeable material 121; the secondary transformer winding SW2 extends between the node SN21 exposed on the top surface 111 and the node SN22 exposed on the bottom surface 112 of the magnetically permeable material 121; the secondary transformer winding SW3 extends between the node SN31 exposed on the top surface 111 and the node SN32 exposed on the bottom surface 112 of the magnetically permeable material 121; the secondary transformer winding SW4 extends between the node SN41 exposed on the top surface 111 and the node SN42 exposed on the bottom surface 112 of the magnetically permeable material 121.

Note further that the fabricator 150 can be configured to control a respective spacing between the primary winding and a secondary winding and a corresponding transformer winding pair. For example, for greater magnetic coupling between the primary winding and the secondary winding of a respective transformer winding pair, the fabricator 150 fabricates the primary winding and the secondary winding of the corresponding transformer winding pair to be closer to each other. If less coupling is desired, the fabricator 150 increases a respective distance between the primary winding and the secondary winding of the corresponding transformer winding pair.

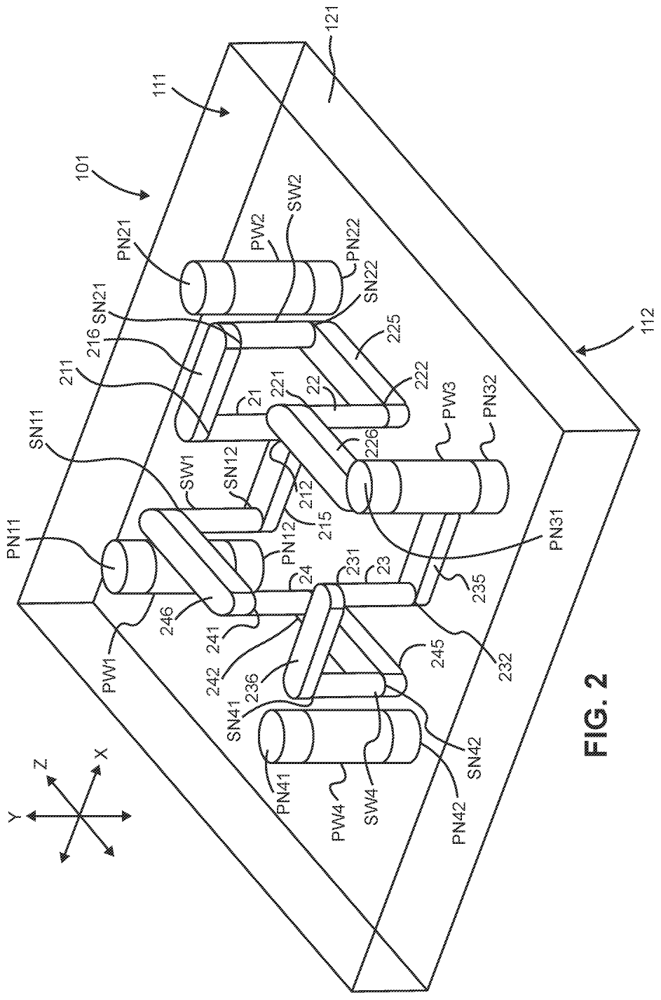

FIG. 2 is an example 3-Dimensional (3-D) diagram illustrating a transformer assembly as discussed herein.

In this example, the fabricator 150 provides serial connectivity of one or more of the secondary windings extending through the layer of magnetically permeable material 121.

For example, the fabricator 150 can be configured to produce the transformer assembly 101 to include electrically conductive paths 21, 22, 23, and 24 (such as fabricated from metal or other suitable one or more materials), each of which extend through the magnetically permeable material 121 at least from the surface 111 to the surface 112.

More specifically, the electrically conductive path 21 extends between the node 211 exposed on the top surface 111 and the node 212 exposed on the bottom surface 112 of the magnetically permeable material 121; the electrically conductive path 22 extends between the node 221 exposed on the top surface 111 and the node 222 exposed on the bottom surface 112 of the magnetically permeable material 121; the electrically conductive path 23 extends between the node 231 exposed on the top surface 111 and the node 232 exposed on the bottom surface 112 of the magnetically permeable material 121; the electrically conductive path 24 extends between the node 241 exposed on the top surface 111 and the node 242 exposed on the bottom surface 112 of the magnetically permeable material 121.

Each of the conductive paths 21, 22, 23, and 24, may extend axially along the y-axis orthogonal to or beyond each of the surface 111 and surface 112.

Yet further, as shown in FIG. 2, the electrically conductive path 21 can be disposed in parallel and between the secondary transformer winding SW1 and the secondary transformer winding SW2; the electrically conductive path 22 can be disposed in parallel and between the secondary transformer winding SW2 and the secondary transformer winding SW3; the electrically conductive path 23 can be disposed in parallel and between the secondary transformer winding SW3 and the secondary transformer winding SW4; the electrically conductive path 24 can be disposed in parallel and between the secondary transformer winding SW4 and the secondary transformer winding SW1; and so on.

As further discussed herein, the fabricator 150 can be configured to produce the assembly 101 to include electrically conductive paths 215, 216, 225, 226, 235, 236, 245, and 246.

In one example, as further discussed below, the electrically conductive paths connect the secondary transformer windings in series.

More specifically, the electrically conductive path 215 is disposed adjacent to or along the surface 112 and provides connectivity between the node SN12 and the node 212; the electrically conductive path 216 is disposed adjacent to or along the surface 111 and provides connectivity between the node 211 and the node SN21.

The electrically conductive path 225 is disposed adjacent to or along the surface 112 and provides connectivity between the node SN22 and the node 222; the electrically conductive path 226 is disposed adjacent to or along the surface 111 and provides connectivity between the node 221 and the node SN31.

The electrically conductive path 235 is disposed adjacent to or along the surface 112 and provides connectivity between the node SN32 and the node 232; the electrically conductive path 236 is disposed adjacent to or along the surface 111 and provides connectivity between the node 231 and the node SN41.

The electrically conductive path 245 is disposed adjacent to or along the surface 112 and provides connectivity between the node SN42 and the node 242; the electrically conductive path 246 is disposed adjacent to or along the surface 111 and provides connectivity between the node 241 and the node SN11.

In accordance with a further example, each of the electrically conductive paths 215, 216, 225, 226, 235, 236, 245, 246 are disposed orthogonal to the secondary transformer windings in the assembly 101. The axial length of each of the electrically conductive path 215, electrically conductive path 216, electrically conductive path 235, and electrically conductive path 236 can be disposed parallel to the X axis. The axial length of each of the electrically conductive path 225, electrically conductive path 226, electrically conductive path 245, and electrically conductive path 246 can be disposed parallel to the Z axis.

Accordingly, the fabricator 150 can be configured to produce a series circuit path including sequential connectivity of one or more of the secondary transformer winding SW1, electrically conductive path 215, electrically conductive path 21, electrically conductive path 216, secondary transformer winding SW2, electrically conductive path 225, electrically conductive path 22, electrically conductive path 226, secondary transformer winding SW3, electrically conductive path 235, electrically conductive path 23, electrically conductive path 236, secondary transformer winding is SW4, electrically conductive path 245, electrically conductive path 24, electrically conductive path 246. Note that the flow of first currents each of the secondary windings (such as in one direction along the y-axis) is opposite the flow of second currents through each of the electrically conductive paths 21, 22, 23, and 24 (such is in a second direction along me Y-axis).

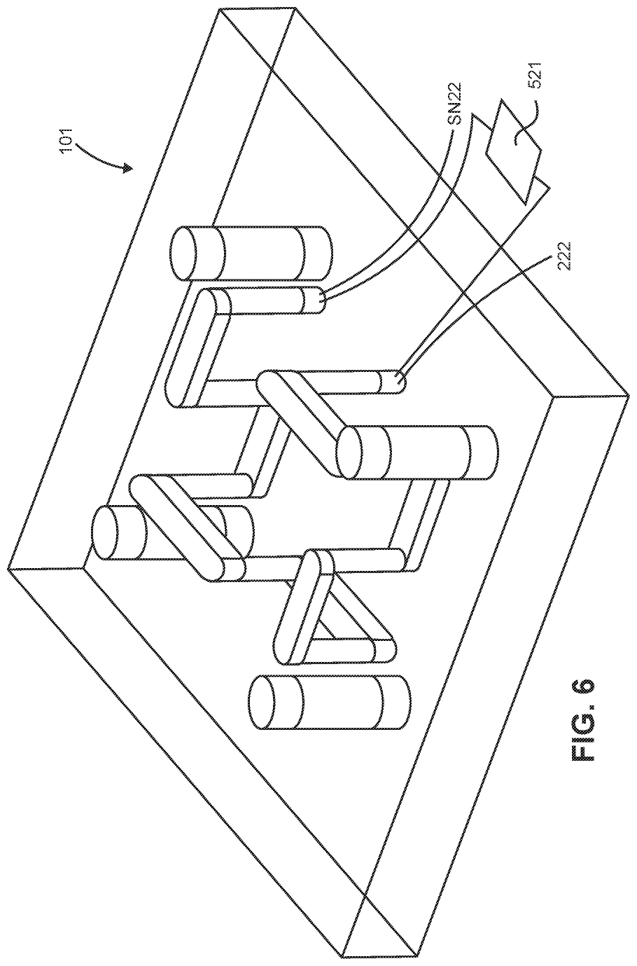

If desired, as further shown in FIG. 6, the electrically conductive path 225 can be removed so that a respective component 521 or multiple components such as one or more of an inductor, switch, etc., can be connected between the node 222 and the node SN22.

Thus, fabrication of the assembly 101 as discussed herein results in a respective electrically conductive path extending from the first node SN12 (on surface 112) of a secondary winding SW1 to a second node SN21 (on surface 111) of a second secondary winding SW2. A first portion (such as electrically conductive path 21) of the first electrically conductive path extends through the layer of magnetically permeable material 121 between a first node 211 on a first surface 111 of the layer and a second node 212 on a second surface 112 of the layer.

A second portion (215) of the first electrically conductive path extends adjacent to the surface 112 of the layer between the first secondary winding path SW1 and the node 212; a third portion (216) of the first electrically conductive path extends adjacent to the surface 111 of the layer between the second secondary winding path SW2 and the second node 211.

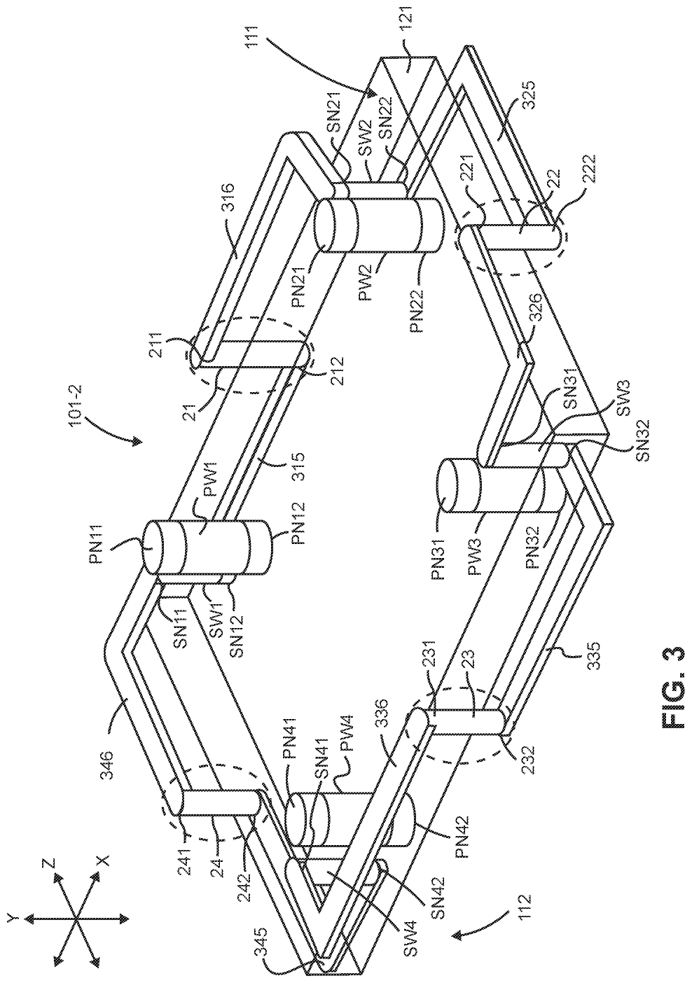

FIG. 3 is an example top view diagram of a transformer assembly as discussed herein.

In this example, the fabricator 150 provides serial connectivity of one or more of the secondary windings extending through the layer of magnetically permeable material 121. However, the electrically conductive paths 21, 22, 23, and 24 can be disposed outside of the layer of electrically conductive material 121.

For example, the fabricator 150 can be configured to produce the transformer assembly 101-2 to include electrically conductive paths 21, 22, 23, and 24 (such as fabricated from metal or other suitable material), each of which does not extend through the magnetically permeable material 121 at least from the surface 111 to the surface 112.

More specifically, in this example, the electrically conductive path 21 resides external to the layer of magnetically permeable material 121 and extends between the node 211 and the node 212; the electrically conductive path 22 resides external to the layer of magnetically permeable material 121 and extends between the node 221 and the node 222; the electrically conductive path 23 resides external to the layer of magnetically permeable material 121 and extends between the node 231 and the node 232; the electrically conductive path 24 resides external to the layer of magnetically permeable material 121 extends between the node 241 and the node 242.

Each of the conductive paths 21, 22, 23, and 24, may extend axially along the y-axis.

As further discussed herein, the fabricator 150 can be configured to produce the assembly 101 to include pairs of electrically conductive paths 315, 316, 325, 326, 335, 336, 345, and 346.

In one example, one or more of the electrically conductive paths 315, 316, 325, 326, 335, 336, 345, and 346 connect the secondary transformer windings in series.

More specifically, the electrically conductive path 315 disposed adjacent to or along the surface 112 provides connectivity between the node SN12 and the node 212; the electrically conductive path 316 disposed adjacent to or along the surface 111 provides connectivity between the node 211 and the node SN21.

The electrically conductive path 325 disposed adjacent to or along the surface 112 provides connectivity between the node SN22 and the node 222; the electrically conductive path 326 disposed adjacent to or along the surface 111 provides connectivity between the node 221 and the node SN31.

The electrically conductive path 335 disposed adjacent to or along the surface 112 provides connectivity between the node SN32 and the node 232; the electrically conductive path 336 disposed adjacent to or along the surface 111 provides connectivity between the node 231 and the node SN41.

The electrically conductive path 345 disposed adjacent to or along the surface 112 provides connectivity between the node SN42 and the node 242; the electrically conductive path 346 disposed adjacent to or along the surface 111 provides connectivity between the node 241 and the node SN11.

In accordance with a further example, each of the electrically conductive paths 315, 316, 325, 326, 335, 336, 345, and 346 are disposed orthogonal (such as in one or more planes parallel to the X-Z plane) to the primary transformer windings and the secondary transformer windings in the assembly 101.

Accordingly, the fabricator 150 can be configured to produce a series circuit path including sequential connectivity of the secondary transformer winding SW1, electrically conductive path 315, electrically conductive path 21, electrically conductive path 316, secondary transformer winding SW2, electrically conductive path 325, electrically conductive path 22, electrically conductive path 326, secondary transformer winding SW3, electrically conductive path 335, electrically conductive path 23, electrically conductive path 336, secondary transformer winding SW4, electrically conductive path 345, electrically conductive path 24, electrically conductive path 346.

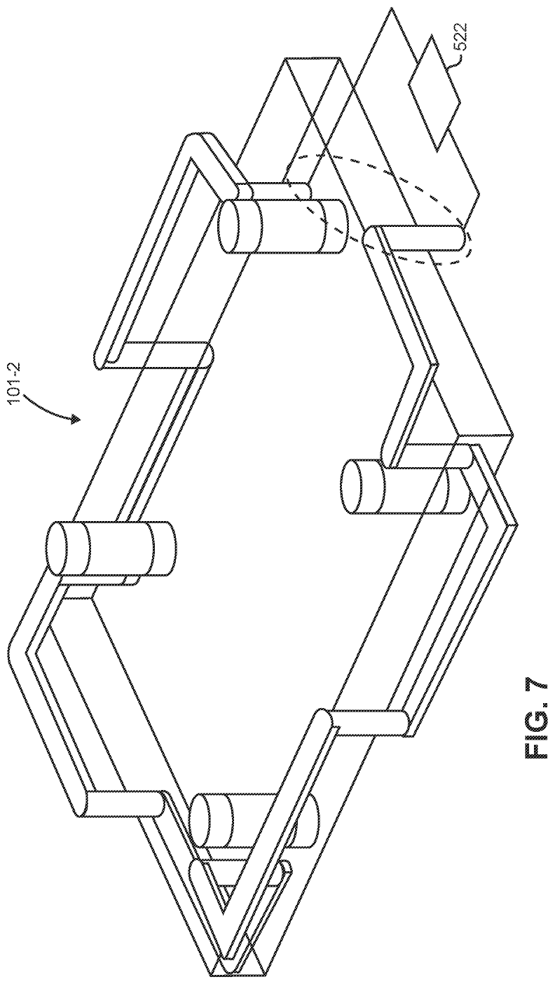

If desired, as further shown in FIG. 7, the electrically conductive path 325 or any one or more other electrically conductive paths can be removed so that a respective component 521 or multiple components such as one or more of an inductor, switch, etc., can be connected between the node 222 and the node SN22 in series with the respective secondary windings.

Thus, fabrication of the assembly 101 as discussed herein results in a respective electrically conductive path extending from the first node SN12 (on surface 112) of a secondary winding SW1 to a second node SN21 (on surface 111) of a second secondary winding SW2. A first portion (such as electrically conductive path 21) of the first electrically conductive path extends outside of the layer of magnetically permeable material 121 between a first node 211 and a node 212. A second portion (315) of the first electrically conductive path extends adjacent to the surface 112 of the layer between the first secondary winding path SW1 and the node 212; a third portion (316) of the first electrically conductive path extends adjacent to the surface 111 of the layer between the node SN21 of the second secondary winding path SW2 and the second node 211.

In a similar manner, multiple segments such as electrically conductive path 325, electrically conductive path 22, and electrically conductive path 326 provide a series path between the node SN22 and the node SN31; multiple segments such as electrically conductive path 335, electrically conductive path 23, and electrically conductive path 336 provide a series path between the node SN32 and the node SN41; multiple segments such as electrically conductive path 345, electrically conductive path 24, and electrically conductive path 346 provide a series circuit path between the node SN42 and the node SN11.

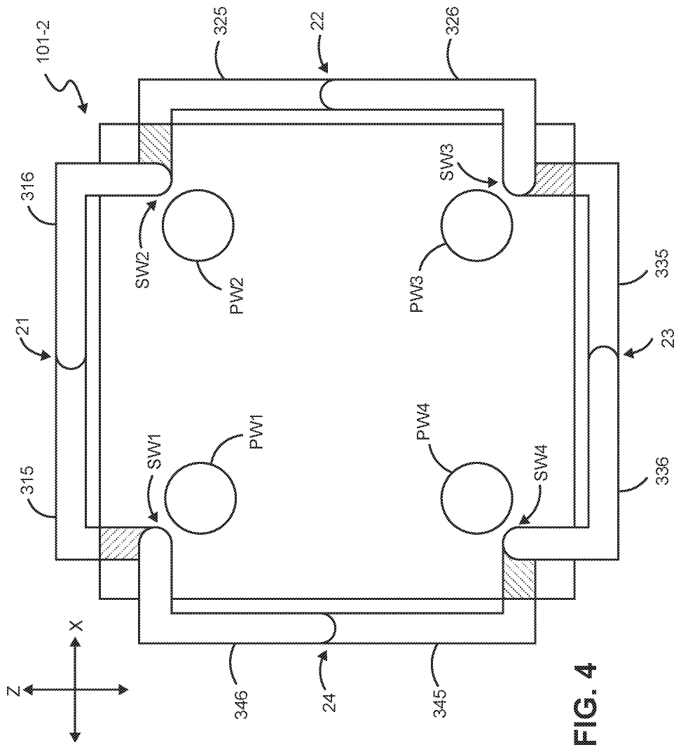

FIG. 4 is an example top view diagram of a respective transformer assembly as discussed herein.

As previously discussed, multiple segments such as electrically conductive path 315, electrically conductive path 21, and electrically conductive path 316 provide a series path between the node SN12 and the node SN21; multiple segments such as electrically conductive path 325, electrically conductive path 22, and electrically conductive path 326 provide a series path between the node SN22 and the node SN31; multiple segments such as electrically conductive path 335, electrically conductive path 23, and electrically conductive path 336 provide a series path between the node SN32 and the node SN41; multiple segments such as electrically conductive path 345, electrically conductive path 24, and electrically conductive path 346 provide a series circuit path between the node SN42 and the node SN11.

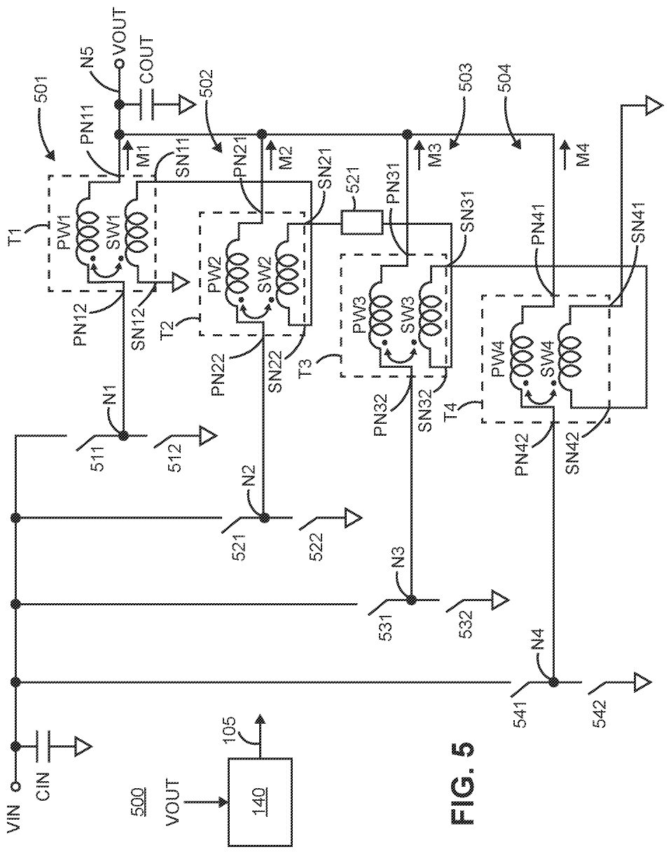

FIG. 5 is an example circuit diagram including implementation of the transformer assembly as discussed herein.

In this example, the power supply circuit 500 implements multiple switches and any of the transformer assemblies as discussed herein to convert the input voltage Vin into the respective output voltage Vout. The power supply circuit 500 includes power converter phase 501, power converter phase 502, power converter phase 503, and power converter phase 504 that operate in parallel to convert the input voltage Vin into the output voltage Vout.

Note that the power supply circuit 500 as discussed herein and corresponding transformer assembly 101 can include any number of transformer winding pairs.

More specifically, in this example of implementing for power converter phases operating in parallel to convert the input voltage into the output voltage, the controller 140 can be configured to monitor a magnitude of the output voltage Vout and generate respective control signals 105 to control the corresponding switches in each of the power converter phases to regulate the magnitude of the output voltage Vout at a desired level.

The first power converter phase 501 includes high side switch circuitry 511, low side switch circuitry 512, and corresponding transformer T1 (including primary winding PW1 and secondary winding SW1 associated with the assembly 101).

The second power converter phase 502 includes high side switch circuitry 521, low side switch circuitry 522, and corresponding transformer T2 (including primary winding PW2 and secondary winding SW2 associated with the assembly 101).

The third power converter phase 503 includes high side switch circuitry 531, low side switch circuitry 532, and corresponding transformer T3 (including primary winding PW3 and secondary winding SW3 associated with the assembly 101).

The fourth power converter phase 504 includes high side switch circuitry 541, low side switch circuitry 542, and corresponding transformer T4 (including primary winding PW4 and secondary winding SW4 associated with the assembly 101).

As further shown, via control of the respective high side switch circuitry 511 and low side switch circuitry 512 (such as associated with a buck converter configuration), the controller 140 controls conveyance of current from the switches (high side switch circuitry 511 and low side switch circuitry 512) connected to node PN12 to produce the current M1 through the primary winding PW1 to the node PN11 and the output node N5 outputting the respective output voltage Vout.

Via control of the respective high side switch circuitry 521 and low side switch circuitry 522 (such as associated with a buck converter configuration), the controller 140 controls conveyance of current from the switches (high side switch circuitry 521 and low side switch circuitry 522) connected to node PN22 to produce the current M2 through the primary winding PW2 to the node PN21 and the output node N5 outputting the respective output voltage Vout.

Via control of the respective high side switch circuitry 531 and low side switch circuitry 532 (such as associated with a buck converter configuration), the controller 140 controls conveyance of current from the switches (high side switch circuitry 531 and low side switch circuitry 532) connected to node PN32 to produce the current M3 through the primary winding PW3 to the node PN31 and the output node N5 outputting the respective output voltage Vout.

Via control of the respective high side switch circuitry 541 and low side switch circuitry 542 (such as associated with a buck converter configuration), the controller 140 controls conveyance of current from the switches (high side switch circuitry 541 and low side switch circuitry 542) connected to node PN42 to produce the current M4 through the primary winding PW4 to the node PN41 and the output node N5 outputting the respective output voltage Vout.

As previously discussed, the series circuit path connecting the secondary transformer windings can be configured to include a respective one or more component 521 or one or more component 522 at any point in the circuit path. In this example, the one or more circuit component 521 is disposed between the node SN21 and the node SN32, although this can vary depending on the example circuit.

FIG. 6 is an example 3-Dimensional (3-D) diagram illustrating an open circuit implementation of a transformer assembly (a.k.a., power converter assembly) as discussed herein.

As previously discussed, and as further shown in FIG. 6, the assembly 101 can be configured to include a first transformer winding pair T1 including a first primary winding PW1 and a first secondary winding SW1 extending through the magnetically permeable material 121. The assembly 101 includes a second transformer winding pair including a second primary winding PW2 and a second secondary winding SW2 extending through the magnetically permeable material 121. The assembly 101 includes a third transformer winding pair including a third primary winding PW3 and a third secondary winding SW3 extending through the magnetically permeable material 121. The assembly 101 includes a fourth transformer winding pair including a fourth primary winding PW4 and a fourth secondary winding SW4 extending through the magnetically permeable material 121.

In one example, the first primary winding path PW1 is disposed diagonally across from the third primary winding path PW3; second primary winding path PW2 is disposed diagonally across from the fourth primary winding path PW4. The first secondary winding path SW1 and the third secondary winding path SW3 are disposed between the first primary winding path PW1 and the third primary winding path PW3. The second secondary winding path SW2 and the fourth secondary winding path SW4 are disposed between the second primary winding path PW2 and the fourth primary winding path PW4.

As previously discussed, the electrically conductive path 225 may be absent from the assembly 101. If desired, the fabricator 150 or other suitable entity can be configured to connect a respective circuit component 521 between the node 222 and the node SN22. In such an instance, the circuit component 521 is connected in series with the secondary transformer windings of the assembly 101.

Accordingly, examples herein include the assembly 101 including a first node (222), a second node (SN22), and a series circuit path extending between the first node and the second node. As previously discussed, the series circuit path (including the electrically conductive paths 21, 22, 23, and 24) connect a combination of the one or more component 521, first secondary winding SW1, second secondary winding SW2, third secondary winding SW3, and the fourth secondary winding SW4 in series with each other. See also FIG. 5.

Via the secondary windings SW1, SW2, SW3, SW4, electrically conductive path 21, electrically conductive path 22, electrically conductive path 23, and electrically conductive path 24, the series circuit path including the secondary windings passes through the layer of magnetically permeable material 111 multiple times.

FIG. 7 is an example 3-Dimensional (3-D) diagram illustrating an open circuit implementation of a transformer assembly as discussed herein.

In this example, the fabricator 150 fabricates the assembly 101-2 such that a combination of the first primary winding path PW1 and the third primary winding path PW3 are disposed between the first secondary winding path SW1 and the third secondary winding path SW3; the fabricator 150 fabricates the assembly 101-2 such that a combination of the second primary winding path PW2 and the fourth primary winding path PW4 are disposed between the second secondary winding path SW2 and the fourth secondary winding path SW4.

Accordingly, as shown in FIG. 7, the series circuit path (such as including one or more of the secondary transformer winding SW1, electrically conductive path 315, electrically conductive path 21, electrically conductive path 316, secondary transformer winding SW2, electrically conductive path 325, electrically conductive path 22, electrically conductive path 326, secondary transformer winding SW3, electrically conductive path 335, electrically conductive path 23, electrically conductive path 336, secondary transformer winding SW4, electrically conductive path 345, electrically conductive path 24, electrically conductive path 346) resides outside of a volumetric portion of the magnetically permeable material 121 disposed between a combination of the first primary winding path PW1, second primary winding path PW2, third primary winding path PW3, and fourth primary winding path PW4.

As previously discussed, the electrically conductive path 225 may be absent from the assembly 101. If desired, the fabricator 150 or other suitable entity can be configured to connect a respective circuit component 521 between the node 222 and the node SN22. In such an instance, the circuit component 521 is connected in series with the secondary transformer windings of the assembly 101.

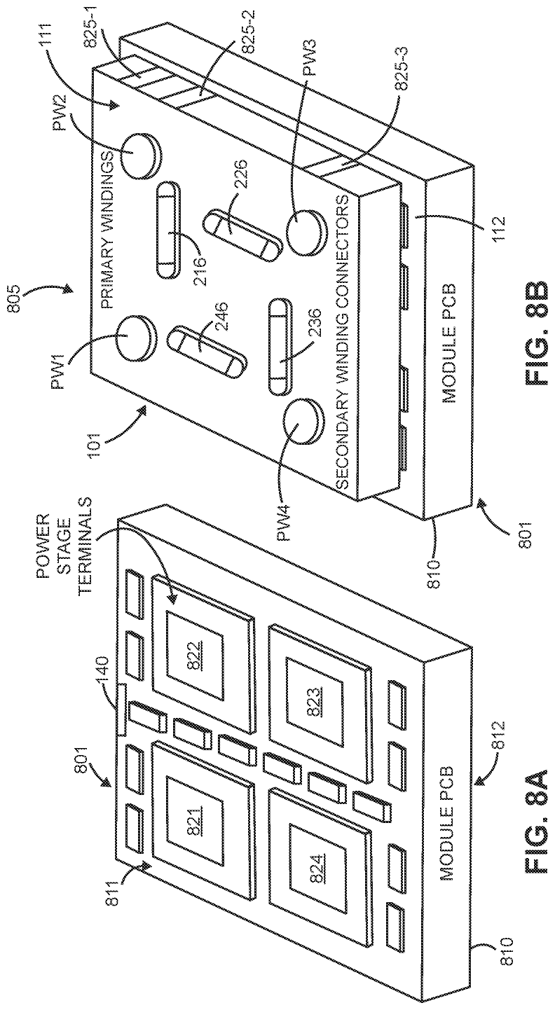

FIG. 8A is an example diagram illustrating a substrate and corresponding circuit components associated with a power converter as discussed herein.

FIG. 8B is an example diagram illustrating a power converter circuit including a substrate and transformer assembly as discussed herein.

In this example, the fabricator 150 receives or fabricates the corresponding assembly 801. The assembly 801 includes substrate 810 as well as other components associated with the power converter circuit (power supply circuitry 500) as previously discussed with respect to FIG. 5. Note that any of the components associated with the power supply circuitry 500 such as capacitor Cin, controller 140, high side switch circuitry 511, low side switch circuitry 512, high side switch circuitry 521, low side switch circuitry 522, high side switch circuitry 531, low side switch circuitry 532, high side switch circuitry 541, low side switch circuitry 542, capacitor Cout, etc., can be disposed on a surface 811 or surface 812 of the substrate 810. The substrate 810 and corresponding assembly 101 support the connectivity of the components shown in the power supply circuitry 500.

As further shown, the circuit board assembly 801 includes multiple surface pads 821, 822, 823, an 824. Surface pad 821 is the same as node N1 of the power supply circuitry 500; surface pad 822 is the same as node N2 of the power supply circuitry 500; surface pad 823 is the same as node N3 of the power supply circuitry 500; surface pad 824 is the same as the node N4 of the power supply circuitry 500.

Assembly 801 can be configured to further include controller 140 as well as any of the switch circuitry such as high side switch circuitry 511, low side switch circuitry 512, high side switch circuitry 521, low side switch circuitry 522, high side switch circuitry 531, low side switch circuitry 532, high side switch circuitry 541, low side switch circuitry 542. As previously discussed, the controller 140 controls operation of the respective switches to control a respective current supplied by each of the surface pads 821, 822, 823, an 824 through a corresponding primary winding.

FIG. 8B illustrates fabrication of the assembly 805 using the assembly 801 as well as the assembly discussed herein. In one example, coupling of the assembly 101 to the assembly 801 to produce the assembly 805 includes: connecting the node PN12 directly to the surface pad 821 (node N1); connecting the node PN22 directly to the surface pad 822 (node N2); connecting the node PN32 directly to the surface pad 823 (node N3); connecting the node PN42 directly to the surface pad 824 (node N4).

As further shown, the top surface 111 of the assembly 101 exposes the nodes PN11, PN21, PN31, and PN41. In one example, all of these nodes are connected together to the node N5 to produce the respective output voltage Vout as logically shown in FIG. 5.

Accordingly, the apparatus such as the assembly 805 as discussed herein can be configured to include substrate 810 as well as assembly 101 (such as a substrate or other suitable entity), where the assembly 101 (such as a substrate) is affixed to the substrate 810. Further, as previously discussed, switch circuitry such as associated with the power supply circuit 500 may be disposed on the substrate 810. The switch circuitry (such as pairs of high side switch circuitry and low side switch circuitry) on the substrate 810 or other suitable entity: controls first current M1 from node N1 through the primary winding PW1 to the node N5; controls second current M2 from node N2 through the primary winding PW2 the node N5; controls current M3 from node N3 through the primary winding PW3 to the node N5; controls current M4 from node N4 through the primary winding PW4 to the node N5.

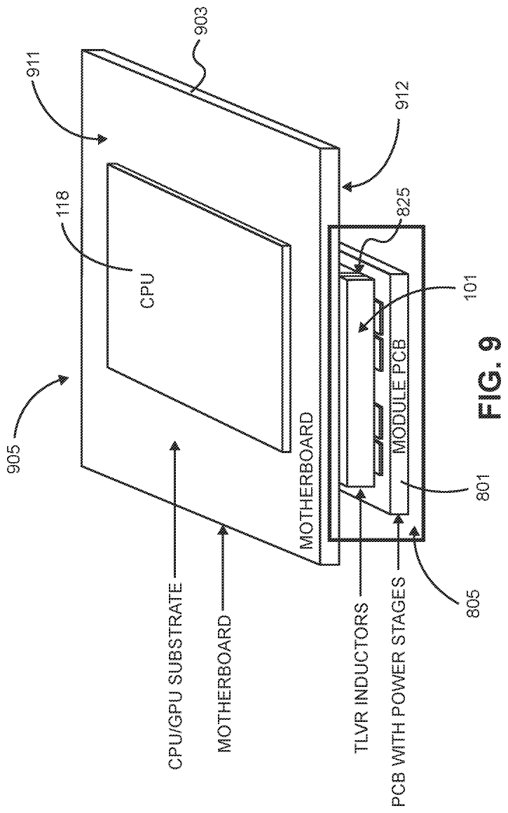

If desired, the assembly 805 can be configured to include additional electrically conductive paths 825-1, 825-2, and 825-3, etc., disposed on an edge of the assembly 101. As shown in FIG. 9, the electrically conductive paths 825-1, 825-2, 825-3, etc., (collectively electrically conductive path 825) convey any suitable signals between the substrate 810 and corresponding load 118 (such as one or more circuit component, a computer processor, circuitry, etc.) affixed to a top of the surface 111.

FIG. 9 is an example 3-Dimensional diagram illustrating stacking of assemblies as discussed herein.

In this example, the fabricator 150 or other suitable entity produces the respective circuit assembly 905 to include the assembly 805 as well as substrate 903 and corresponding power load 118. Fabrication can include the fabricator 150 coupling the assembly 805 and corresponding exposed nodes (such as PN11, PN12, PN13, and PN14) to the pads disposed on surface 912 of the substrate 903 (such as a mother board or other suitable entity). The substrate 903 includes one or more electrically conductive paths extending from the or more pads disposed on the bottom surface 912 to the top surface 911 of the substrate 903. Via the one or more electrically conductive path extending through the substrate 903, the substrate 903 conveys output current (M1, M2, M3, M4) and corresponding output voltage Vout from the primary windings PW1, PW2, PW3, and PW4 to the dynamic load 118.

Accordingly, the apparatus such as the 905 can be configured to include the substrate 903 sandwiched between the assembly 805 and the dynamic load 118. In other words, the substrate 903 is disposed between the dynamic load 118 and the assembly 805. The surface 111 of the assembly 805 is directly coupled to the surface 912 of the substrate 903. The substrate 903 and corresponding electrically conductive paths through the substrate 903 convey the respective output current M1, M2, M3, M4, as well as the output voltage Vout from the assembly 101 to the load 118.

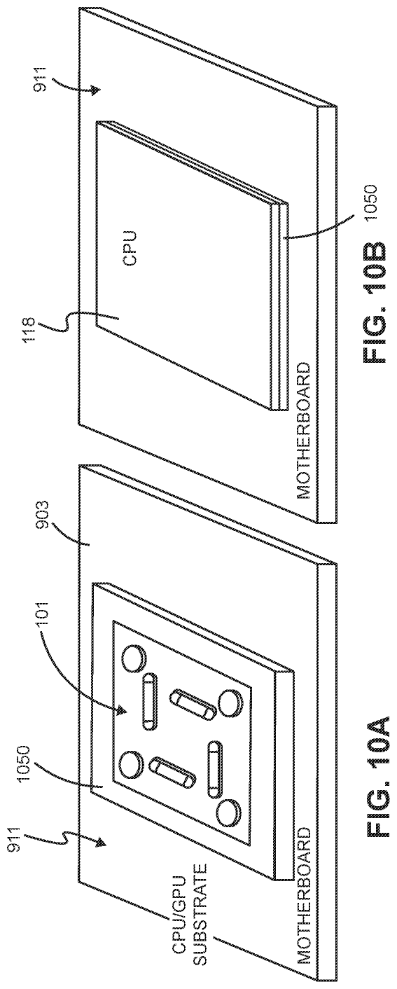

FIG. 10A is an example 3-Dimensional diagram illustrating implementation of a transformer assembly between a host substrate and a respective load as discussed herein.

In this example, the fabricator 150 embeds the assembly 101 and/or switch circuitry in the substrate 1050. As previously discussed, the switch circuitry may control delivery of respective current (M1, M2, M3, M4) and include high side switch circuitry 511, low side switch circuitry 512, high side switch circuitry 521, low side switch circuitry 522, high side switch circuitry 531, low side switch circuitry 532, high side switch circuitry 541, low side switch circuitry 542.

As shown in FIG. 10B, a circuit component such as the load 118 is powered by the current M1, M2, M3, M4 supplied by the assembly 101. The load 118 is affixed to the top surface of the substrate 1050. The bottom surface of the substrate 1050 is coupled to the top surface 911 of the substrate 903. Accordingly, the substrate 1050 (assembly including the embedded assembly 101) can be disposed between the load 118 and the substrate 911.

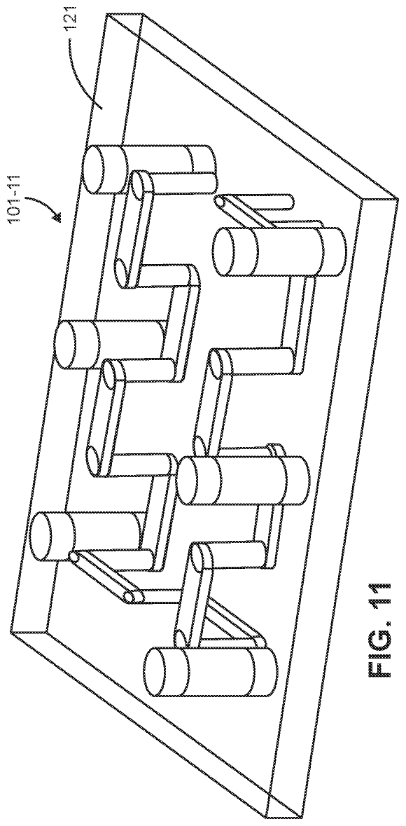

FIG. 11 is an example diagram illustrating implementation of a transformer assembly as discussed herein.

As previously discussed, the assembly 101 can be configured to include any number of transformer winding pairs. In this example, the example assembly 101-11 includes 6 transformer winding pairs. As previously discussed, and as further shown in FIG. 11, the secondary windings can be connected in series via supplemental electrically conductive paths.

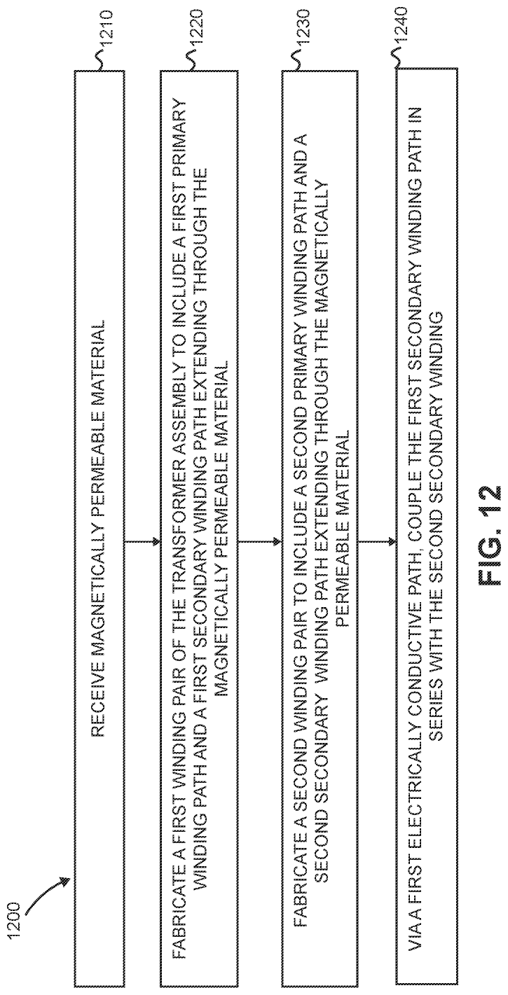

FIG. 12 is an example method of fabricating a respective transformer assembly as discussed herein.

In processing operation 1210, the fabricator 150 receives magnetically permeable material.

In processing operation 1220, the fabricator 150 fabricates a first winding pair of the transformer assembly to include a first primary winding path and a first secondary winding path extending through the magnetically permeable material.

In processing operation 1230, the fabricator 150 fabricates a second winding pair to include a second primary winding path and a second secondary winding path extending through the magnetically permeable material.

In processing operation 1240, via a first electrically conductive path, the fabricator 150 couples the first secondary winding path in series with the second secondary winding.

Note again that techniques herein are well suited for use in circuit assembly applications such as those providing power delivery to one or more loads. However, it should be noted that the disclosure of matter herein is not limited to use in such applications and that the techniques discussed herein are well suited for other applications as well.

While this invention has been particularly shown and described with references to preferred aspects thereof, it will be understood by those skilled in the art that various changes in form and details may be made therein without departing from the spirit and scope of the present application as defined by the appended claims. Such variations are intended to be covered by the scope of this present application. As such, the foregoing description in the present disclosure is not intended to be limiting. Rather, any limitations to the invention are presented in the following claims.

We claim:

1. An apparatus comprising:
a layer of magnetically permeable material;
a first winding pair including a first primary winding path and a first secondary winding path extending through the magnetically permeable material;
a second winding pair including a second primary winding path and a second secondary winding path extending through the magnetically permeable material; and
a first electrically conductive path coupling the first secondary winding path in series with the second secondary winding path.

2. The apparatus as in claim 1, wherein a first portion of the first electrically conductive path extends through the layer of magnetically permeable material between a first node on a first surface of the layer and a second node on a second surface of the layer.

3. The apparatus as in claim 2, wherein a second portion of the first electrically conductive path extends adjacent to the first surface of the layer between the first secondary winding path and the first node; and
wherein a third portion of the first electrically conductive path extends adjacent to the second surface of the layer between the second secondary winding path and the second node.

4. The apparatus as in claim 1, wherein the first electrically conductive path does not pass through the layer of magnetically permeable material.

5. The apparatus as in claim 4, wherein the first secondary winding path extends axially to a first node on a first surface of the layer;
wherein the second secondary winding path extends axially to a second node on a second surface of the layer; and
wherein the first electrically conductive path extends between the first node and the second node.

6. The apparatus as in claim 1 further comprising:
a third winding pair including a third primary winding path and a third secondary winding path extending through the magnetically permeable material;
a fourth winding pair including a fourth primary winding path and a fourth secondary winding path extending through the magnetically permeable material; and
a second electrically conductive path coupling the third secondary winding path in series with the fourth secondary winding path.

7. The apparatus as in claim 6 further comprising:
a third electrically conductive path coupling the second secondary winding path in series with the third secondary winding path; and
a fourth electrically conductive path coupling the fourth secondary winding path in series with the first secondary winding path.

8. The apparatus as in claim 6, further comprising:
a first node;
a second node; and
a series circuit path extending between the first node and the second node, the series circuit path connecting a combination of the first secondary winding, second secondary winding, third secondary winding, and the fourth secondary winding in series with each other.

9. The apparatus as in claim 8, wherein the series circuit path passes through the layer of magnetically permeable material multiple times.

10. The apparatus as in claim 1 further comprising:
a circuit component disposed between a first node and a second node; and
wherein the first electrically conductive path is a series circuit path extending between the first node and the second node, the series circuit path connecting a combination of the first secondary winding and the second secondary winding in series.

11. The apparatus as in claim 1, wherein the circuit component is an inductor.

12. The apparatus as in claim 1 further comprising:
a third winding pair including a third primary winding path and a third secondary winding path extending through the magnetically permeable material;
a fourth winding pair including a fourth primary winding path and a fourth secondary winding path extending through the magnetically permeable material; and
a series circuit path including the first electrically conductive path, the series circuit path connecting the first secondary winding path, second secondary winding path, third secondary winding path and the fourth secondary winding path in series.

13. The apparatus as in claim 12, wherein the first primary winding path is disposed diagonally across from the third primary winding path;
wherein the second primary winding path is disposed diagonally across from the fourth primary winding path;
wherein the first secondary winding path and the third secondary winding path are disposed between the first primary winding path and the third primary winding path; and
wherein the second secondary winding path and the fourth secondary winding path are disposed between the second primary winding path and the fourth primary winding path.

14. The apparatus as in claim 12, wherein a combination of the first primary winding path and the third primary winding path are disposed between the first secondary winding path and the third secondary winding path; and
wherein a combination of the second primary winding path and the fourth primary winding path are disposed between the second secondary winding path and the fourth secondary winding path.

15. The apparatus as in claim 12, wherein the series circuit path resides outside of a volumetric portion of the magnetically permeable material disposed between a combination of the first primary winding path, second primary winding path, third primary winding path, and fourth primary winding path.

16. The apparatus as in claim 1, wherein the layer of magnetically permeable material is a first substrate, the apparatus further comprising:
a second substrate, the first substrate affixed to the second substrate; and
switch circuitry disposed on the second substrate, the switch circuitry operative to control first current through the first primary winding path and second current through the second primary winding path.

17. The apparatus as in claim 16 further comprising:
a third substrate, the first substrate affixed to the third substrate; and
a dynamic load powered by the first current and the second current, the third substrate disposed between the first substrate and the dynamic load.

18. The apparatus as in claim 1 further comprising:
a first substrate, wherein the layer of magnetically permeable material is embedded within the first substrate; and
switch circuitry operative to control first current through the first primary winding path and second current through the second primary winding path.

19. The apparatus as in claim 18 further comprising:
a circuit component powered by the first current and the second current; and
a second substrate, the first substrate affixed to the second substrate, the first substrate disposed between the second substrate and the circuit component.

20. A method comprising:
receiving magnetically permeable material;
fabricating a first winding pair to include a first primary winding path and a first secondary winding path extending through the magnetically permeable material;
fabricating a second winding pair to include a second primary winding path and a second secondary winding path extending through the magnetically permeable material; and
via a first electrically conductive path, coupling the first secondary winding path in series with the second secondary winding path.
